(19) United States
(12) Patent Application Publication
(10) Pub. No.: US 2006/0163624 A1
(43) Pub. Date: Jul. 27, 2006

(54) Semiconductor device, and manufacturing method thereof

(75) Inventor: Takashi Kuroi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/319,740

(22) Filed: Dec. 29, 2005

(30) Foreign Application Priority Data
Jan. 13, 2005 (JP) 2005-006192

(51) Int. Cl. H01L 29/76; H01L 21/28

(52) U.S. Cl. 257/288; 438/583

(57) ABSTRACT

The present invention provides a semiconductor device having a fully silicided gate electrode (full-silicide gate electrode) and a manufacturing method thereof, that has no problem of the increase in junction leak current, can increase a thickness of a metal silicide film formed on a source/drain region, and can form a fully silicided gate electrode and metal silicide film with one silicide forming process. A metal silicide film is formed such that its upper main face becomes higher than a semiconductor substrate. The thickness of the metal silicide film can be increased in order to secure a sufficient distance from an interface between the metal silicide film and the semiconductor substrate to an interface between a source/drain diffusion layer and the semiconductor substrate. As a result, the thickness of the metal silicide layer can be increased while avoiding the increase in junction leak current, even if a full-silicide gate electrode is formed.

### BACKGROUND OF THE INVENTION

1. Field of the Invention

The present invention relates to a semiconductor device, and more particularly to a semiconductor device wherein a gate electrode and source/drain region are silicided, and a manufacturing method thereof.

2. Description of the Background Art

A semiconductor element has been difficult to operate with high speed, since parasitic resistance has increased with the advance of microfabrication. An increase in resistance of the gate electrode is considered to be one of factors of increasing the parasitic resistance. In order to reduce the resistance of the gate electrode, a technique for siliciding the upper section of polysilicon, that is a material of the gate electrode, has conventionally been used widely. The silicided gate electrode has increased resistance with reduced gate length, so that a technique for using metal for the gate electrode has been proposed.

However, in case where metal is used for the gate electrode, there arises a problem that threshold voltages of a N-type MISFET (Metal-Insulator-Semiconductor Field Effect Transistor) and a P-type MISFET cannot simultaneously be made appropriate due to a work function that is inevitably determined by a metal material.

A conventional technique has been reported, as a technique for solving this problem, in which a gate electrode is completely metal-silicided (fully silicided) (refer to, e.g., Z. Krivokapic et. al., “Nickel Silicide Metal Gate FDSOI Devices with Improved Gate Oxide Leakage”, International Electron Device Meeting 2002 p271-274).

However, in a semiconductor device disclosed in the aforementioned literature, a metal silicide film of the source/drain region is formed in a semiconductor substrate. Therefore, increasing the thickness of the metal silicide film cannot afford a sufficient distance from an interface between the metal silicide film and the semiconductor substrate to an interface between a source/drain diffusion layer and the semiconductor substrate. As a result, increase in junction leak current is produced when voltage is applied to the source/drain region.

When the source/drain diffusion layer is deepened in order to solve this problem, a short-channel effect of MISFET cannot be suppressed, thereby unable to reduce the gate length.

From the aforementioned reasons, the thickness of the metal silicide film is restricted, and hence, the restricted thickness causes the increase in resistance of the source/drain region, so that high-speed operation is made difficult.

Further, a gate electrode and metal silicide film of source/drain region have different thickness in the conventional art. Therefore, the gate electrode and the metal silicide film of the source/drain region are required to be separately silicided, which means a silicide forming process is required to be performed twice.

As a result of the increase in the number of times of the silicide forming process, the involved interlayer film forming process, CMP (Chemical Mechanical Polishing) process, and the like are further required. Therefore, there arise problems of making the manufacturing process complicated and increasing manufacturing cost.

### SUMMARY OF THE INVENTION

An object of the present invention is to provide semiconductor device having a fully silicided gate electrode (full-silicide gate electrode) and a manufacturing method thereof, that has no problem of the increase in junction leak current, can increase a thickness of a metal silicide film formed on a source/drain region, and can form a fully silicided gate electrode and metal silicide film with one silicide forming process.

According to a first aspect of the present invention, a semiconductor device includes a full-silicide gate electrode and a source/drain region.

The full-silicide gate electrode is formed on a semiconductor substrate via a gate insulating film, and is fully silicided.

The source/drain region is formed such that its upper main face becomes higher than the semiconductor substrate so as to sandwich the full-silicide gate electrode.

The source/drain region has a metal silicide film at least on the side of the upper main face.

According to the first aspect of the present invention, the upper main face of the source/drain region is formed higher than the semiconductor substrate and has the metal silicide film on the side of the upper main face, whereby the thickness of the metal silicide film can be increased without causing a problem of the increase in junction leak current.

Further, the thickness of the metal silicide film can be increased, so that the full-silicide gate electrode and the metal silicide film can be simultaneously formed by performing a silicide process once.

According to a second aspect of the present invention, a manufacturing method of a semiconductor device that includes a full-silicide gate electrode which is formed on a semiconductor substrate via a gate insulating film and is fully silicided, and a source/drain region which has an upper main face formed higher than the semiconductor substrate so as to sandwich the full-silicide gate electrode, the source/drain region including a metal silicide film at least on the side of the upper main face includes the following steps (a) to (d).

The step (a) is to form a polysilicon gate electrode formed of a polysilicon film on the semiconductor substrate via the gate insulating film. The step (b) is to form a silicon film on the'semiconductor substrate in the source/drain region. The step (c) is to form a metal film so as to cover the polysilicon gate electrode and silicon film. The step (d) is to simultaneously silicide the whole polysilicon gate electrode and a part of or whole of the silicon film, thereby forming the full-silicide gate electrode and metal silicide film.

According to the second aspect of the present invention, the thickness of the metal silicide film can be increased, whereby the thickness of the full-silicide gate electrode and the thickness of the metal silicide film can substantially be equal to each other. As a result of forming the silicon film having a thickness substantially equal to that of the polysilicon gate electrode, the polysilicon gate electrode and the silicon film can simultaneously be silicided by performing a silicide forming process once. Therefore, the manufacturing process is simplified compared to a conventional method, thereby being capable of reducing manufacturing cost.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a configuration of a semiconductor device according to a first embodiment;

FIGS. 2 to 5 are sectional views showing a manufacturing method of the semiconductor device according to the first embodiment;

FIG. 6 is a sectional view showing a configuration of a semiconductor device according to a second embodiment;

FIGS. 7 to 9 are sectional views showing a manufacturing method of the semiconductor device according to the second embodiment;

FIG. 10 is a sectional view showing a modification of the manufacturing method of the semiconductor device according to the second embodiment;

FIG. 11 is a sectional view showing a configuration of a semiconductor device according to a third embodiment;

FIGS. 12 to 17 are sectional views showing a manufacturing method of the semiconductor device according to the third embodiment;

FIG. 18 is a sectional view showing a configuration of a semiconductor device according to a fourth embodiment;

FIGS. 19 to 22 are sectional views showing a manufacturing method of the semiconductor device according to the fourth embodiment;

FIG. 23 is a sectional view showing a configuration of a semiconductor device according to a fifth embodiment;

FIGS. 24 to 26 are sectional views showing a manufacturing method of the semiconductor device according to the fifth embodiment;

FIG. 27 is a sectional view showing a configuration of a semiconductor device according to a sixth embodiment;

FIG. 28 is a sectional view showing a configuration of a semiconductor device according to a seventh embodiment;

FIGS. 29 to 33 are sectional views showing the manufacturing method of the semiconductor device according to the seventh embodiment;

FIG. 34 is a sectional view showing a configuration of a semiconductor device according to an eighth embodiment; and

FIG. 35 is a sectional view showing a configuration of a semiconductor device according to a ninth embodiment.

### DESCRIPTION OF THE PREFERRED EMBODIMENTS

### First Embodiment

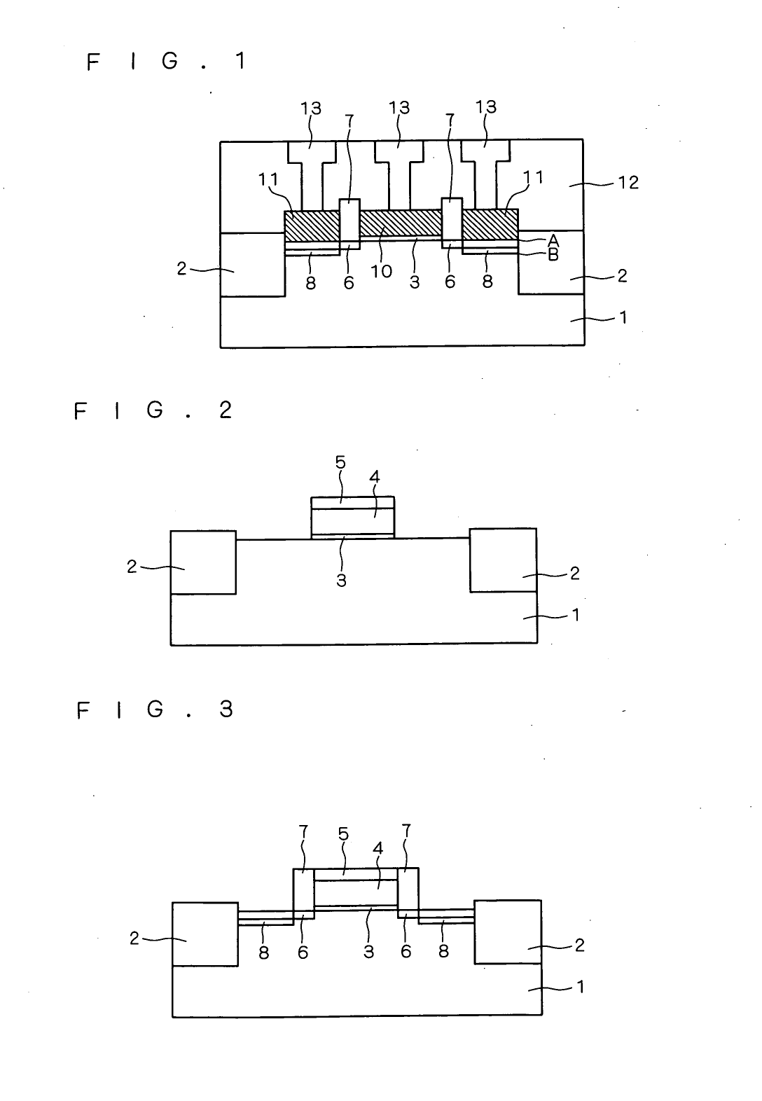

FIG. 1 is a sectional view showing a configuration of a semiconductor device according to a first embodiment of the present invention.

An element isolation oxide film 2 is formed on a semiconductor substrate I so as to encircle a circumference of an element formation region. A full-silicide gate electrode 10, that is fully silicided (perfectly silicided) gate electrode, is formed via a gate insulating film 3 on the semiconductor substrate 1 in the element formation region. Sidewall insulating films 7 are formed at the sidewalls of the gate insulating film 3 and full-silicide gate electrode 10. Source/drain extension layers 6 are formed on the surface of the semiconductor substrate 1 below the sidewall insulating films 7.

Source/drain regions having source/drain diffusion layers 8 and metal silicide films 11 are formed so as to sandwich the full-silicide gate electrode 10. The upper main face of each of the source/drain regions is formed so as to be higher than the semiconductor substrate 1, and the metal silicide film 11 is formed at least on the side of the upper main face of the source/drain region. In FIG. 1, the metal silicide film 11 is formed from the semiconductor substrate 1 up to the upper main face of the source/drain region.

Each of the source/drain diffusion layers 8 is formed on the surface of the semiconductor substrate 1 so as to sandwich a channel region below the full-silicide gate electrode 10. The source/drain diffusion layer 8 is formed to be deeper than the source/drain extension layer 6. The metal silicide film 11 is formed to have a thickness substantially equal to the thickness of the full-silicide gate electrode 10.

An interlayer film 12 is formed on the semiconductor substrate 1. Mounted in the interlayer film 12 are the full-silicide gate electrode 10 and wiring layers 13 for establishing a contact to the metal silicide film 11.

A manufacturing method of the semiconductor device according to this embodiment will be explained with reference to FIGS. 2 to 5.

Firstly, the element isolation oxide film 2 is formed on the semiconductor substrate 1, and then, a silicon nitride oxide film having a thickness of about 1.5 nm, a polysilicon film having a thickness of about 100 nm and a silicon oxide film having a thickness of about 20 nm are sequentially formed (not shown).

Subsequently, the silicon oxide film, polysilicon film and silicon nitride film are sequentially patterned with a photoengraving pattern as a mask, thereby forming a polysilicon gate electrode 4 formed of the polysilicon film on the semiconductor substrate 1 via the gate insulating film 3 (FIG. 2). At this time, a silicon oxide film 5 is formed on the polysilicon gate electrode 4.

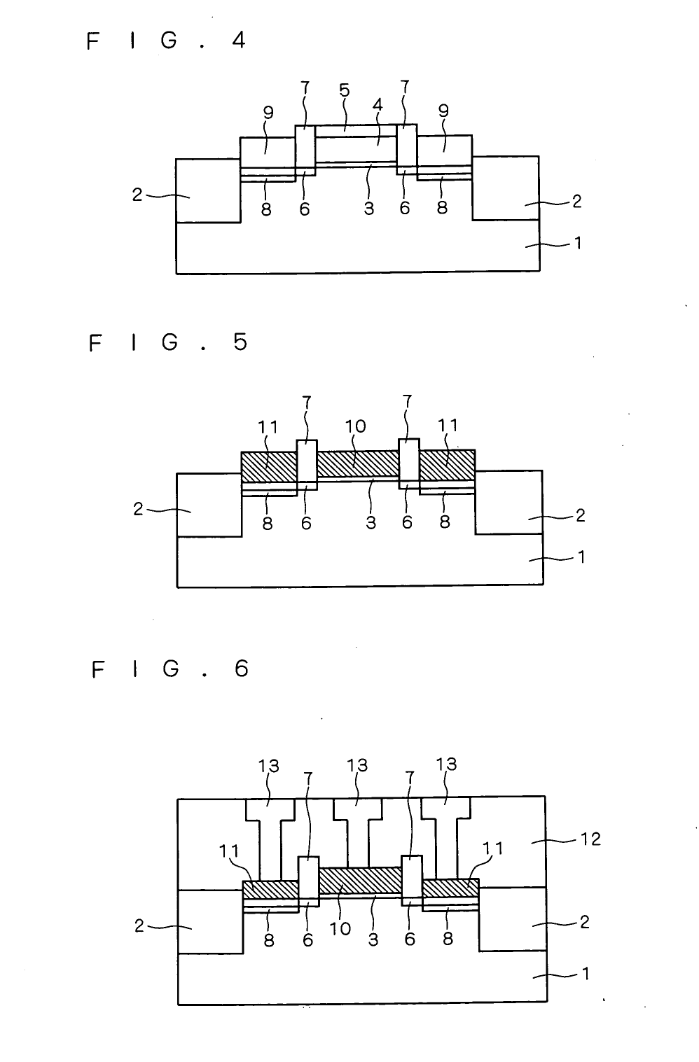

Then, arsenic ion is implanted to form the source/drain extension layer 6, and then, a silicon nitride film having a thickness of 30 nm is deposited on the entire face. This silicon nitride film is etched back to form the sidewall insulating films 7 on the sidewalls of the silicon oxide film 5, polysilicon gate electrode 4 and gate insulating film 3. Thereafter, arsenic ion is implanted to form the source/drain diffusion layer 8 (FIG. 3) Subsequently, a silicon film 9 is deposited with a thickness of about 100 nm only on the source/drain diffusion layer 8 by a selective CVD method (FIG. 4). Specifically, the silicon film 9 is formed on the semiconductor substrate 1 in the source/drain region. The silicon film 9 is formed to have a thickness substantially equal to that of the polysilicon gate electrode 4.

Subsequently, the silicon oxide film 5 on the polysilicon gate electrode 4 is removed to expose the surface of the polysilicon gate electrode 4. Then, a nickel film (metal film) having a thickness of about 70 nm is deposited on the entire surface of the semiconductor substrate so as to cover the polysilicon gate electrode 4 and the silicon film 9, and heat treatment with about 400° C. is applied thereon, thereby metal-siliciding all of the silicon film 9 and polysilicon gate electrode 4 on the source/drain diffusion layer 8.

Thereafter, the unreacted nickel film is removed to form the full-silicide (nickel-silicide) gate electrode 10 and the metal silicide film (nickel-silicide film) 11 on the source/drain diffusion layers 8 (FIG. 5).

Herein, the thickness of the full-silicide gate electrode 10 and the thickness of the metal silicide film 11 on the source/drain diffusion layer 8 are substantially equal to each other.

As explained above, the polysilicon gate electrode 4 and the silicon film 9 are simultaneously silicided, thereby forming the full-silicide gate electrode 10 and the metal silicide film 11 on the source/drain diffusion layer 8.

Subsequently, the interlayer film 12 is formed on the semiconductor substrate 1, and a contact is opened to establish an electrical contact between the full-silicide gate electrode 10 and the metal silicide film 11. Wiring layers 13 are formed to complete the semiconductor device shown in FIG. 1.

In this embodiment, the metal silicide film 11 is formed on the semiconductor substrate 1, whereby the sufficient distance from an interface A (see FIG. 1) between the metal silicide film 11 and the semiconductor substrate 1 to an interface B between the source/drain diffusion layer 8 and the semiconductor substrate 1 can be secured. Consequently, the thickness of the metal silicide layer 11 can be increased while avoiding the increase in junction leak current, even if the full-silicide gate electrode 10 is formed.

Further, the thickness of the metal silicide film 11 can be increased, thereby being capable of reducing resistance. Therefore, high-speed operation of a semiconductor element (MISFET) can be realized.

It should be noted that the metal silicide film 11 may be formed only above the semiconductor substrate 1 (at least on the side of the upper main face of the source/drain region) by siliciding a part of the silicon film 9. With this configuration, resistance can be reduced due to the increased thickness of the source/drain region.

Further, the thickness of the metal silicide film 11 can be increased in this embodiment, the thickness of the full-silicide gate electrode 10 and the thickness of the metal silicide film 11 can be made substantially equal to each other. As a result of forming the silicon film 9 having the thickness substantially equal to the thickness of the polysilicon gate electrode 4, the polysilicon gate electrode 4 and the silicon film 9 can simultaneously be silicided by performing a silicide forming process once. Therefore, a manufacturing process is simplified compared to the conventional method, thereby being capable of reducing manufacturing cost.

Moreover, upon forming the wiring layers 13, the depth of the contact becomes constant with respect to the fill-silicide gate electrode 10 and the metal silicide film 11, so that the process margin for the contact hole is enlarged to thereby be capable of enhancing yield.

In this embodiment, the silicon film 9 having the thickness substantially equal to that of the polysilicon gate electrode 4 is deposited. However, a thicker silicon film 9 may be deposited and the metal silicide film may be formed above the silicon film 9 simultaneous with the silicidation of the polysilicon gate electrode 4. With this configuration, the thickness of the metal silicide film can be increased while avoiding the increase in junction leak current.

### Second Embodiment

FIG. 6 is a sectional view showing a configuration of a semiconductor device according to a second embodiment of the present invention.

An element isolation oxide film 2 is formed on a semiconductor substrate 1 so as to encircle a circumference of an element formation region. A full-silicide gate electrode 10, that is fully silicided gate electrode, is formed via a gate insulating film 3 on the semiconductor substrate 1 in the element formation region. Sidewall insulating films 7 are formed at the sidewalls of the gate insulating film 3 and full-silicide gate electrode 10. Source/drain extension layers 6 are formed on the surface of the semiconductor substrate 1 below the sidewall insulating films 7.

Source/drain regions having source/drain diffusion layers 8 and metal silicide films 11 are formed so as to sandwich the full-silicide gate electrode 10. Each of the source/drain diffusion layers 8 is formed on the surface of the semiconductor substrate 1 so as to sandwich the channel region below the full-silicide gate electrode 10. The source/drain diffusion layer 8 is formed to be deeper than the source/drain extension layer 6.

The metal silicide film 11 is formed on the source/drain diffusion layer 8. The metal silicide film 11 is formed to have a thickness smaller than the thickness of the full-silicide gate electrode 10. Further, the metal silicide film 11 on the source/drain diffusion layer 8 contains an element for suppressing the silicide reaction.

An interlayer film 12 is formed on the semiconductor substrate 1. Mounted in the interlayer film 12 are the full-silicide gate electrode 10 and wiring layers 13 for establishing a contact to the metal silicide film 11.

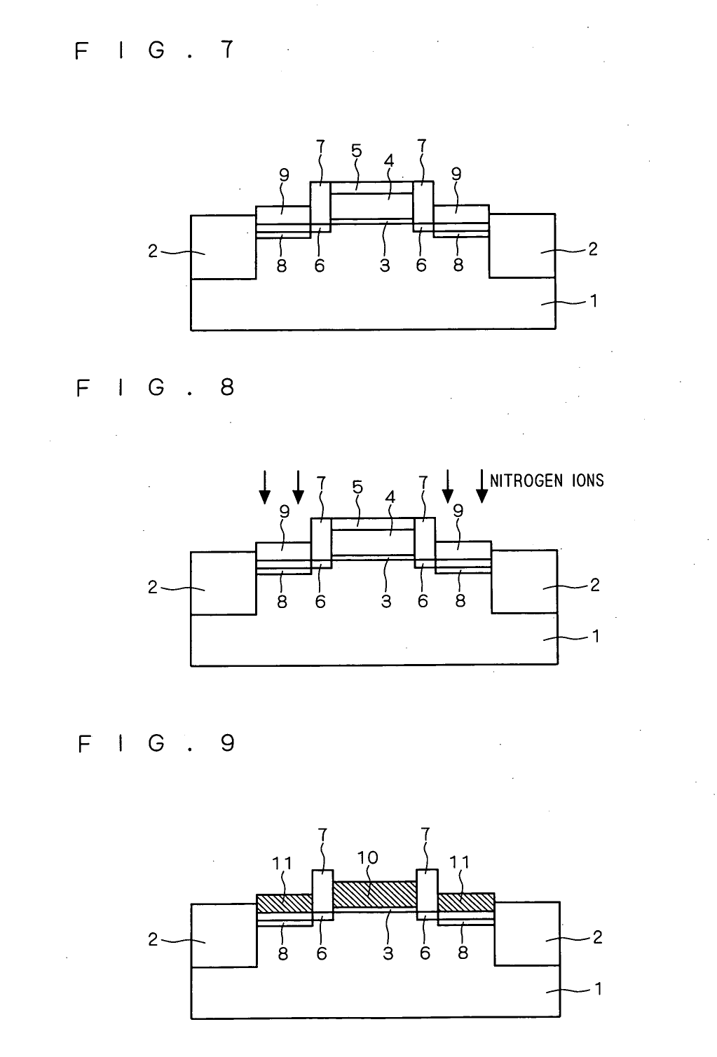

A manufacturing method of the semiconductor device according to this embodiment will be explained with reference to FIG. 7 to 9.

Like the first embodiment, the polysilicon gate electrode 4, source/drain diffusion layer 8 and the like are formed (see FIGS. 2 and 3), and then, the silicon film 9 is deposited only on the source/drain diffusion layer 8 with a thickness of about 50 nm by a selective CVD method (FIG. 7). At this time, the silicon film 9 is formed to have the thickness smaller than that of the polysilicon gate electrode 4.

Subsequently, an element (nitrogen) for suppressing the silicidation is implanted into the silicon film 9 (FIG. 8). At this time, the silicon oxide film 5 is formed on the polysilicon gate electrode 4, so that nitrogen ions are not implanted in the polysilicon gate electrode 4.

Subsequently, the silicon oxide film 5 on the polysilicon gate electrode 4 is removed to expose the surface of the polysilicon gate electrode 4. Then, a nickel film having a thickness of about 70 nm is deposited, and heat treatment with about 400° C. is applied thereon, thereby metal-siliciding all of the silicon film 9 and polysilicon gate electrode 4 on the source/drain diffusion layer 8. Thereafter, the unreacted nickel film is removed. Consequently, the full-silicide gate electrode 10 and the metal silicide film 11 on the source/drain diffusion layer 8 are formed (FIG. 9).

Herein, the silicon film 9 on the source/drain diffusion layer 8 contains nitrogen suppressing the silicidation, with the result that the thickness of the metal silicide film 11 is smaller than the thickness of the full-silicide gate electrode 10. The thickness of the metal silicide film 11 on the source/drain diffusion layer 8 can be controlled by the amount of nitrogen to be implanted and the thickness of the silicon film 9 to be deposited.

Then, the interlayer film 12 is formed, contact is opened, and wiring layers 13 are formed, thereby completing the semiconductor element (MISFET) shown in FIG. 6.

In this embodiment, the metal silicide film 11 is formed on the semiconductor substrate 1, whereby the sufficient distance from an interface between the metal silicide film 11 and the semiconductor substrate 1 to an interface between the source/drain diffusion layer 8 and the semiconductor substrate 1 can be secured. Consequently, the thickness of the metal silicide layer 11 can be increased while avoiding the increase in junction leak current, even if the full-silicide gate electrode 10 is formed.

Further, since the thickness of the metal silicide film 11 can be increased, resistance can be reduced, thereby being capable of realizing high-speed operation of the semiconductor element.

Moreover, the metal silicide film 11 on the source/drain diffusion layer 8 contains an element suppressing the silicidation. Therefore, the metal silicide film 11 that is thinner than the full-silicide gate electrode 10 can be formed in simultaneous with the full-silicide gate electrode 10.

Since the metal silicide film 11 is thinner than the full-silicide gate electrode 10, the sufficient distance between the metal silicide film 11 and the full-silicide gate electrode 10 can be secured. Therefore, short-circuit between both electrodes can effectively be avoided, thereby enhancing yield.

The silicide forming process is performed once in this embodiment, so that the manufacturing process is simplified compared to the conventional method, thereby being capable of reducing manufacturing cost.

A step between the metal silicide film 11 on the source/drain diffusion layer 8 and the full-silicide gate electrode 10 can be made smaller than as conventionally. Accordingly, upon forming the wiring layers, the process margin for the contact hole is enlarged to thereby be capable of enhancing yield.

First Modification

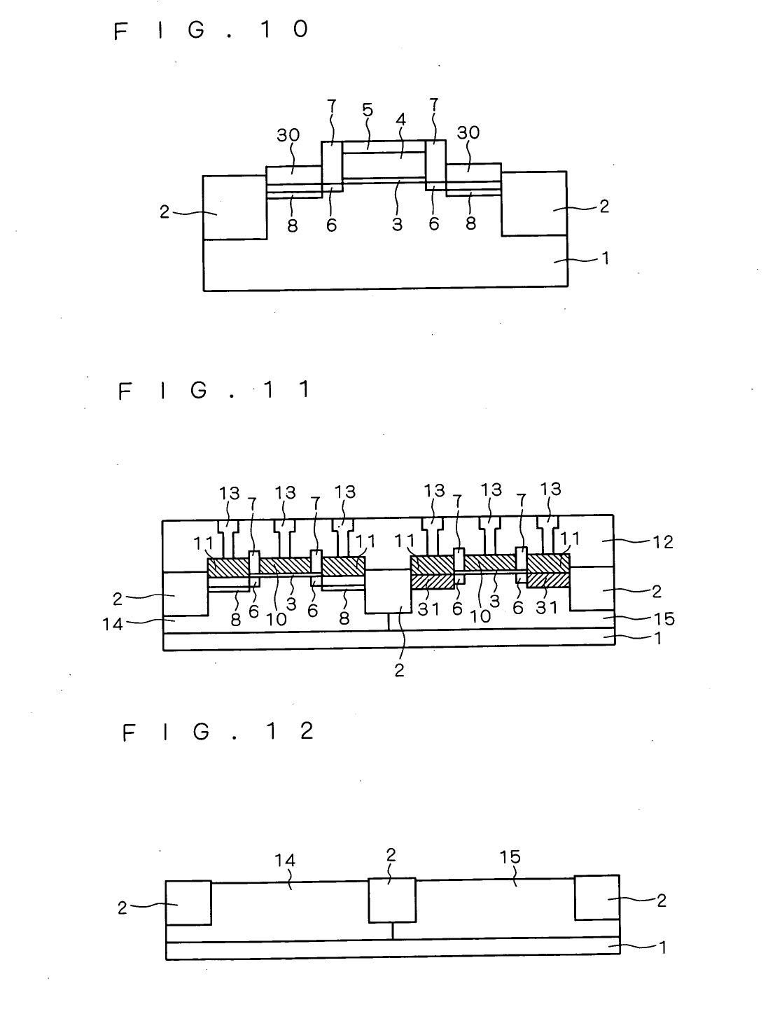

A modification of the manufacturing method of the semiconductor device according to this embodiment will be explained with reference to FIG 10.

Like the first embodiment, the polysilicon gate electrode 4, source/drain diffusion layer 8 and the like are formed (see FIGS. 2 and 3), and then, a silicon film 30 is deposited only on the source/drain diffusion layer 8 with a thickness of about 50 nm by a selective CVD method. At this time, nitrogen ions are not implanted with ion implantation, but nitrogen is doped in-situ in the silicon film (FIG. 10). Specifically, the silicon film 30 is formed as implanting the element for suppressing the silicidation. Therefore, the silicon film 30 contains nitrogen.

Subsequently, the silicon oxide film 5 on the polysilicon gate electrode 4 is removed to expose the surface of the polysilicon gate electrode 4. Then, a nickel film having a thickness of about 70 nm is deposited, and heat treatment with about 400° C. is applied thereon, thereby metal-siliciding all of the silicon film 30 and polysilicon gate electrode 4 on the source/drain diffusion layer 8. Thereafter, the unreacted nickel film is removed. Consequently, the full-silicide gate electrode 10 and the metal silicide film 11 on the source/drain diffusion layer 8 are formed (FIG. 9).

Herein, the silicon film 30 on the source/drain diffusion layer 8 contains nitrogen suppressing the silicidation, with the result that the thickness of the metal silicide film 11 on the source/drain diffusion layer 8 is smaller than the thickness of the full-silicide gate electrode 10. The thickness of the metal silicide film 11 on the source/drain diffusion layer 8 can be controlled by the amount of nitrogen to be implanted and the thickness of the silicon film 9 to be deposited.

Then, the interlayer film 12 is formed, contact is opened, and wiring layers 13 are formed, thereby completing the semiconductor element (MISFET) (see FIG. 6).

In this modification, nitrogen is implanted simultaneous with the formation of the silicon film 30, whereby ion implanting process for implanting nitrogen can be omitted.

### Third Embodiment

FIG. 11 is a sectional view showing a configuration of a semiconductor device according to a third embodiment.

The semiconductor device according to this embodiment is a CMISFET (Complementary Metal-Insulator-Semiconductor Field Effect Transistor) in which an N-type MISFET and a P-type MISFET are formed respectively on an N-type MISFET formation region and a P-type MISFET formation region, which are insulatingly separated from each other by the element isolation oxide film 2.

The element isolation oxide film 2 is formed on a semiconductor substrate 1, and a p well 14 is formed on the N-type MISFET formation region and an n well 15 is formed on the P-type MISFET formation region.

A full-silicide gate electrode 10 is formed via a gate insulating film 3. A source/drain diffusion layer 8 made of N-type dopant is formed on the N-type MISFET formation region via the channel region. Formed on the P-type MISFET region is a silicon germanium source/drain layer 31 formed of silicon germanium layer to which P-type dopant and germanium are added.

Metal silicide films 11 are formed on the source/drain diffusion layer 8 on the N-type MISFET and the silicon germanium source/drain layer 31 on the P-type MISFET, respectively. Herein, the metal silicide film 11 extends to the surface of the semiconductor substrate 1. Its thickness is substantially same as the thickness of the full-silicide gate electrode 10. Further, the metal silicide film 11 contains germanium.

Subsequently, a manufacturing method of the semiconductor device according to this embodiment will be explained with reference to FIGS. 12 to 17.

The element isolation oxide film 2 is formed on the semiconductor substrate 1, and the p well 14 is formed on the N-type MISFET formation region with multi-implantation of boron ions and the n well 15 is formed on the P-type MISFET formation region with multi-implantation of phosphor ions (FIG. 12).

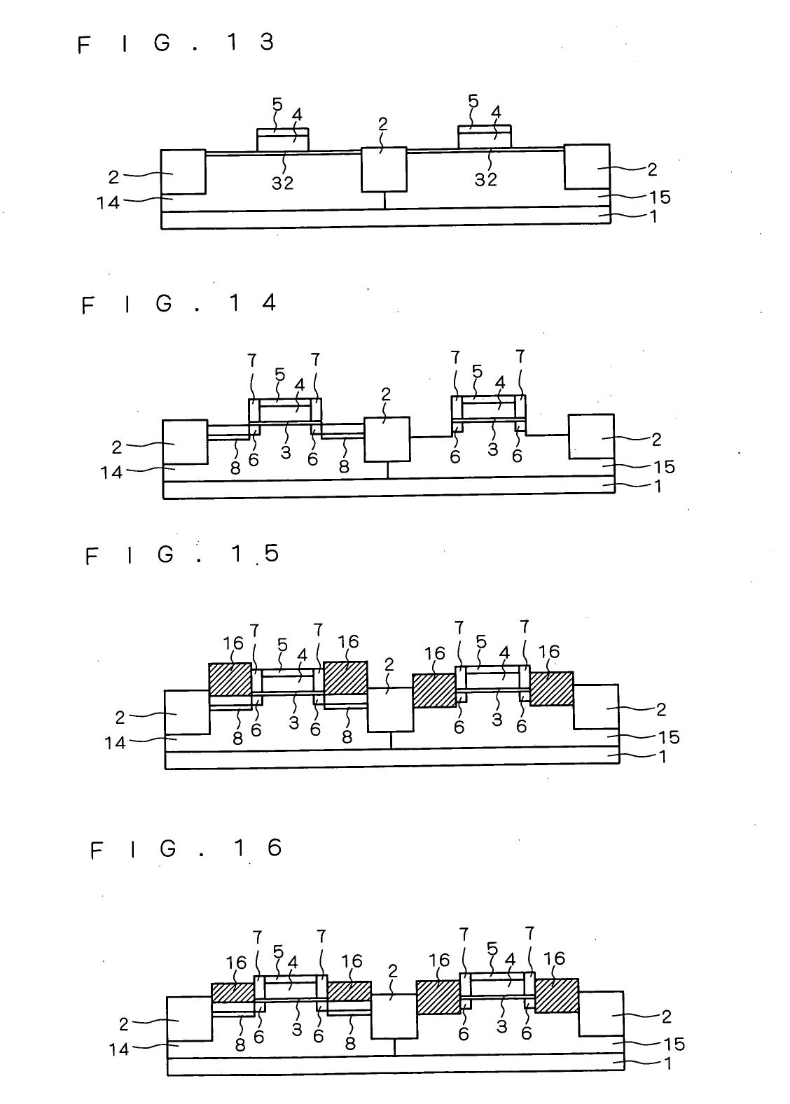

Then, a silicon nitride oxide film 32 having a thickness of about 1.5 nm, polysilicon film having a thickness of about 100 nm and silicon oxide film having a thickness of about 20 nm are sequentially formed. Next, the silicon oxide film and polysilicon film are sequentially patterned with a photoengraving pattern as a mask, thereby forming a polysilicon gate electrode 4 (FIG. 13).

Subsequently, arsenic ions are implanted into the N-type MISFET formation region and boron ions are implanted into the P-type MISFET formation region, thereby forming source/drain extension layer 6. Thereafter, silicon nitride film having a thickness of about 30 nm is deposited on the entire surface and etched back, thereby forming sidewall insulating films 7 on the sidewalls of the gate electrode 4.

Then, arsenic ions are implanted into the N-type MISFET formation region, thereby forming a source/drain diffusion layer 8. Thereafter, the semiconductor substrate 1 in the P-type MISFET source/drain formation region is etched by about 50 nm to form a recess region (see FIG. 14). The recess region is formed on the semiconductor substrate 1 so as to sandwich the polysilicon gate electrode 4.

Subsequently, a silicon germanium film (silicon film containing germanium) 16 to which boron is doped is deposited only on the source/drain diffusion layer 8 on the N-type MISFET and the recess region on the P-type MISFET with a thickness of about 150 nm by a selective CVD method (FIG. 15).

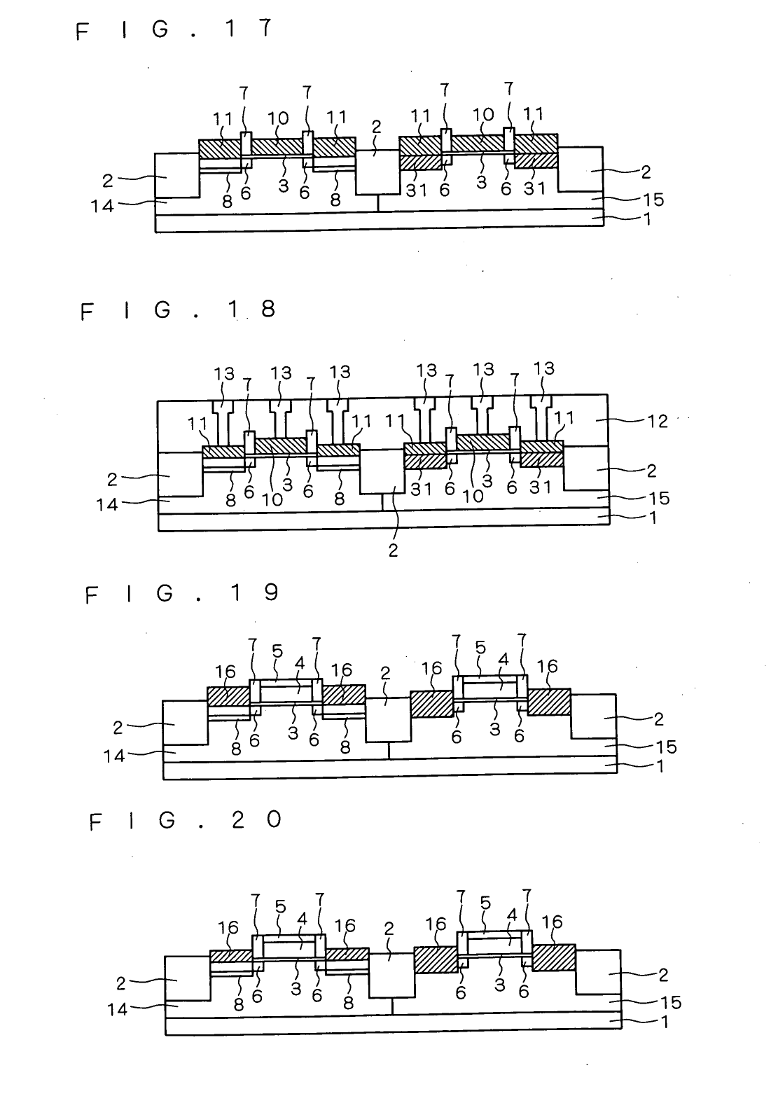

Then, the silicon germanium film 16 on the N-type MISFET formation region is removed by about 50 nm, thereby making its thickness about 100 nm (FIG. 16).

Subsequently, the silicon oxide film 5 on the polysilicon gate electrode 4 is removed to expose the surface of the polysilicon gate electrode 4. Then, a nickel film having a thickness of about 70 nm is deposited on the entire surface of the semiconductor substrate 1, and heat treatment with about 400° C. is applied thereon, thereby metal-siliciding all of the silicon germanium film 16 on the source/drain diffusion layer 8 in the N-type MISFET, a part of the silicon germanium film 16 on the P-type MISFET region and polysilicon gate electrode 4. Thereafter, the unreacted nickel film is removed to form the full-silicide gate electrode 10 and the metal silicide film 11 (FIG. 17).

The thickness of the full-silicide gate electrode 10 and the thickness of the metal silicide film 11 are substantially equal to each other. The silicon germanium film 16 on the N-type MISFET formation region is perfectly silicided.

Subsequently, the interlayer film 12 is formed, a contact is opened and wiring layers 13 are formed, thereby completing the semiconductor element (CMISFET) shown in FIG. 11.

In this embodiment, the metal silicide film 11 is formed on the source/drain diffusion layer 8, whereby the sufficient distance between the interface of the metal silicide film 11 and the junction face of the source/drain diffusion layer 8 can be secured. Consequently, the increase in junction leak current can be avoided.

Further, since the thickness of the metal silicide film 11 on the source/drain diffusion layer 8 can be increased, resistance can be reduced, thereby being capable of realizing high-speed operation of the semiconductor element.

Moreover, the source/drain layer on the P-type MISFET is the silicon germanium source/drain layer (silicon germanium layer) 31, so that compressive stress is applied on the channel region. Therefore, moving speed of carrier is improved, thereby being capable of performing high-speed operation.

The silicide forming process is performed once in this embodiment, so that the manufacturing process is simplified compared to the conventional method, thereby being capable of reducing manufacturing cost.

Additionally, upon forming the wiring layers 13, the depth of the contact becomes constant with respect to the full-silicide gate electrode 10 and the metal silicide film 11, so that the process margin for the contact hole is enlarged to thereby be capable of enhancing yield.

Further, in this embodiment, the formation of the silicon germanium film 16 is simultaneously performed on the P-type MISFET and N-type MISFET. Therefore, the process is simplified compared to the case wherein two processes are required, i.e., a process for forming a silicon germanium film on the P-type MISFET and a process for forming a silicon film on the N-type MISFET. Accordingly, manufacturing cost can be reduced.

It should be noted that, although only the source/drain layer on the P-type MISFET is the silicon germanium source/drain layer in this embodiment, the source/drain layer on the N-type MISFET may also be formed of a silicon germanium film.

### Fourth Embodiment

Next, a configuration of a semiconductor device according to a fourth embodiment will be explained with reference to FIG. 18.

An element isolation oxide film 2 is formed on a semiconductor substrate 1, and a p well 14 is formed on an N-type MISFET formation region and an n well 15 is formed on a P-type MISFET formation region. A silicided full-silicide gate electrode 10 is formed via a gate insulating film 3. A source/drain diffusion layer 8 made of N-type dopant is formed on the N-type MISFET formation region via a channel region below the full-silicide gate electrode 10. Formed on the P-type MISFET region is a silicon germanium source/drain layer 31 to which P-type dopant and germanium are added.

A metal silicide film 11 is formed on the source/drain diffusion layer 8 and the silicon germanium source/drain layer 31. Herein, the metal silicide film 11 on the source/drain diffusion layer 8 extends up to the surface of the semiconductor substrate 1. Its thickness is smaller than that of the full-silicide gate electrode 10. Similarly, the silicide film 11 on the silicon germanium source/drain layer 31 also extends up to the surface of the semiconductor substrate 1. Its thickness is smaller than that of the full-silicide gate electrode 10. Further, the metal silicide film 11 contains a material for suppressing the silicide reaction and germanium.

Subsequently, a manufacturing method of the semiconductor device according to this embodiment will be explained with reference to FIGS. 19 to 22.

Like the third embodiment, a polysilicon gate electrode 4 and other components are formed, and then, the source/drain diffusion layer 8 is formed on the N-type MISFET formation region and a recess region is formed on the P-type MISFET formation region (see FIG. 14).

Subsequently, a silicon germanium film 16 to which boron is doped is deposited with a thickness of about 100 nm on the source/drain diffusion layer 8 on the N-type MISFET and the recess region on the P-type MISFET by a selective CVD method (FIG. 19).

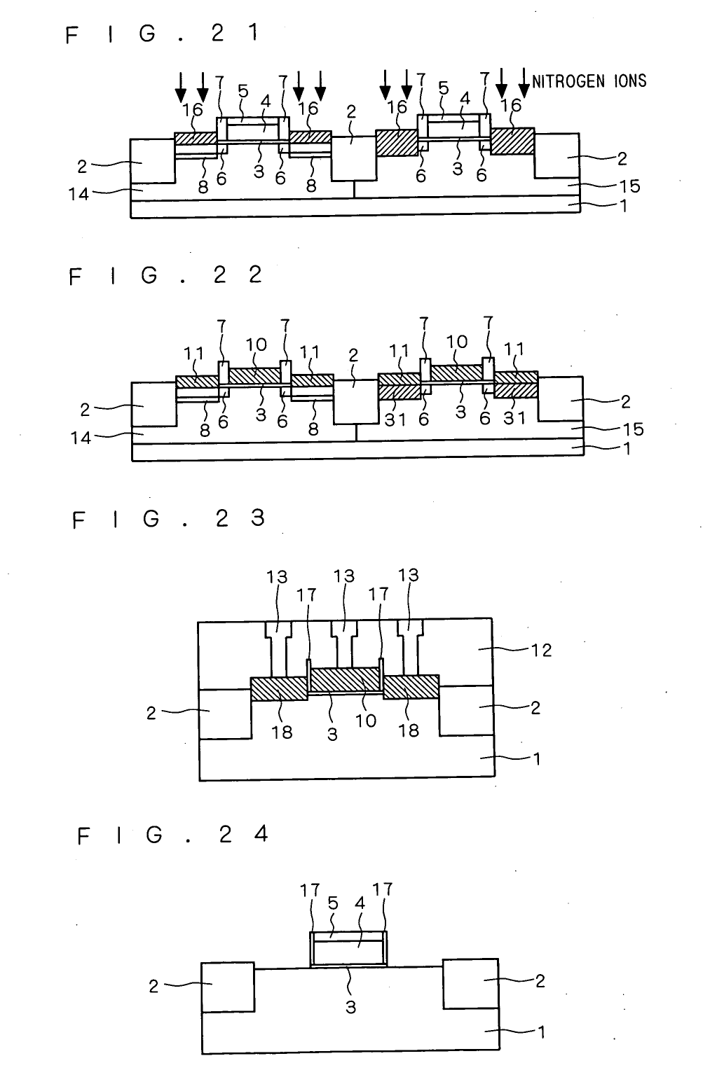

Next, the silicon germanium film 16 on the N-type MISFET formation region is removed by about 50 nm, thereby making its thickness about 50 nm (FIG. 20).

Then, nitrogen ions are implanted into the silicon germanium film 16 (FIG. 21). At this time, since the silicon oxide film 5 is formed on the polysilicon gate electrode 4, nitrogen is not implanted into the polysilicon gate electrode 4.

Subsequently, the silicon oxide film 5 on the polysilicon gate electrode 4 is removed to expose the surface of the polysilicon gate electrode 4. Then, a nickel film having a thickness of about 70 nm is deposited on the entire surface of the semiconductor substrate 1, and heat treatment with about 400° C. is applied thereon, thereby metal-siliciding all of the silicon germanium film 16 on the source/drain diffusion layer 8 in the N-type MISFET, a part of the silicon germanium film 16 on the P-type MISFET formation region and the polysilicon film of the polysilicon gate electrode 4. Thereafter, the unreacted nickel film is removed to form the full-silicide gate electrode 10 and the metal silicide film 11 (FIG. 22).

Herein, the silicon film 9 on the source/drain diffusion layer 8 contains nitrogen suppressing the silicidation, with the result that the thickness of the metal silicide film 11 is smaller than the thickness of the full-silicide gate electrode 10. The thickness of the metal silicide film 11 can be controlled by the amount of nitrogen to be implanted and the thickness of the silicon film 9 to be deposited. Herein, the silicon germanium film 16 on the N-type MISFET formation region is completely silicided.

Then, the interlayer film 12 is formed, contact is opened, and wiring layers 13 are formed, thereby completing the semiconductor element (CMISFET) shown in FIG. 18.

In this embodiment, the metal silicide film 11 is formed on the semiconductor substrate 1, whereby a sufficient distance from an interface between the metal silicide film 11 and the semiconductor substrate 1 to an interface between the source/drain diffusion layer 8 or the silicon germanium source/drain layer 31 and the semiconductor substrate 1 can be secured. Consequently, the thickness of the metal silicide layer 11 can be increased while avoiding the increase in junction leak current.

Further, since the thickness of the metal silicide film 11 can be increased, resistance can be reduced, thereby being capable of realizing high-speed operation of the semiconductor element.

Moreover, the source/drain layer on the P-type MISFET is the silicon germanium source/drain layer 31, so that compressive stress is applied on the channel region. Therefore, driving ability of the P-type MISFET is improved, thereby being capable of performing high-speed operation.

Since the metal silicide film 11 is thinner than the full-silicide gate electrode 10, the sufficient distance between the metal silicide film 11 and the full-silicide gate electrode 10 can be secured. Therefore, short-circuit between both electrodes can effectively be avoided, thereby enhancing yield.

The silicide forming process is performed once in this embodiment, so that the manufacturing process is simplified compared to the conventional method, thereby being capable of reducing manufacturing cost.

Additionally, a step between the metal silicide film 11 and the full-silicide gate electrode 10 can be made smaller than as conventionally. Accordingly, upon forming the wiring layers, the process margin for the contact hole is enlarged to thereby be capable of enhancing yield.

Further, in this embodiment, the formation of the silicon germanium film 16 is simultaneously performed on the P-type MISFET formation region and N-type MISFET formation region. Therefore, the process is simplified compared to the case wherein two CVD processes are required, i.e., a process for forming a silicon germanium film on the P-type MISFET and a process for forming a silicon film on the N-type MISFET. Accordingly, manufacturing cost can be reduced.

Modification

Subsequently, a modification of the manufacturing method of the semiconductor device according to this embodiment will be explained.

According to the aforementioned process, a polysilicon gate electrode 4 and other components are formed, and then, the source/drain diffusion layer 8 is formed on the N-type MISFET formation region and a recess region is formed on the P-type MISFET formation region (see FIG. 14).

Subsequently, a silicon germanium layer 16 to which boron is doped is deposited with a thickness of about 100 nm on the source/drain diffusion layer 8 on the N-type MISFET and the recess region on the P-type MISFET by a selective CVD method.

Nitrogen is implanted in-situ upon forming the silicon germanium film 16 in this modification.

Next, the silicon germanium film 16 on the N-type MISFET formation region is removed by about 50 nm, thereby making its thickness about 50 nm, by the same manner as in the aforementioned manufacturing method.

Subsequently, the silicon oxide film 5 on the polysilicon gate electrode 4 is removed to expose the surface of the polysilicon gate electrode 4. Then, a nickel film having a thickness of about 70 nm is deposited on the entire surface of the semiconductor substrate 1, and heat treatment with about 400° C. is applied thereon, thereby metal-siliciding all of the silicon germanium film 16 on the source/drain diffusion layer in the N-type MISFET, a part of the silicon germanium film 16 on the P-type MISFET region and polysilicon gate electrode 4. Thereafter, the unreacted nickel film is removed to form the full-silicide gate electrode 10 and the metal silicide film 11 (FIG. 22).

Herein, the silicon germanium film 16 contains nitrogen suppressing the silicidation, with the result that the thickness of the metal silicide film 11 is smaller than the thickness of the full-silicide gate electrode 10.

The thickness of the metal silicide film 11 can be controlled by the amount of nitrogen to be implanted and the thickness of the silicon germanium film 16 to be deposited.

Herein, the silicon germanium film 16 on the N-type MISFET formation region is completely silicided. Then, the interlayer film 12 is formed, contact is opened, and wiring layers 13 are formed, thereby completing the semiconductor element (CMISFET) shown in FIG. 18.

In this modification, nitrogen is implanted simultaneous with the formation of the silicon germanium film 16, whereby ion implanting process for implanting nitrogen can be omitted.

### Fifth Embodiment

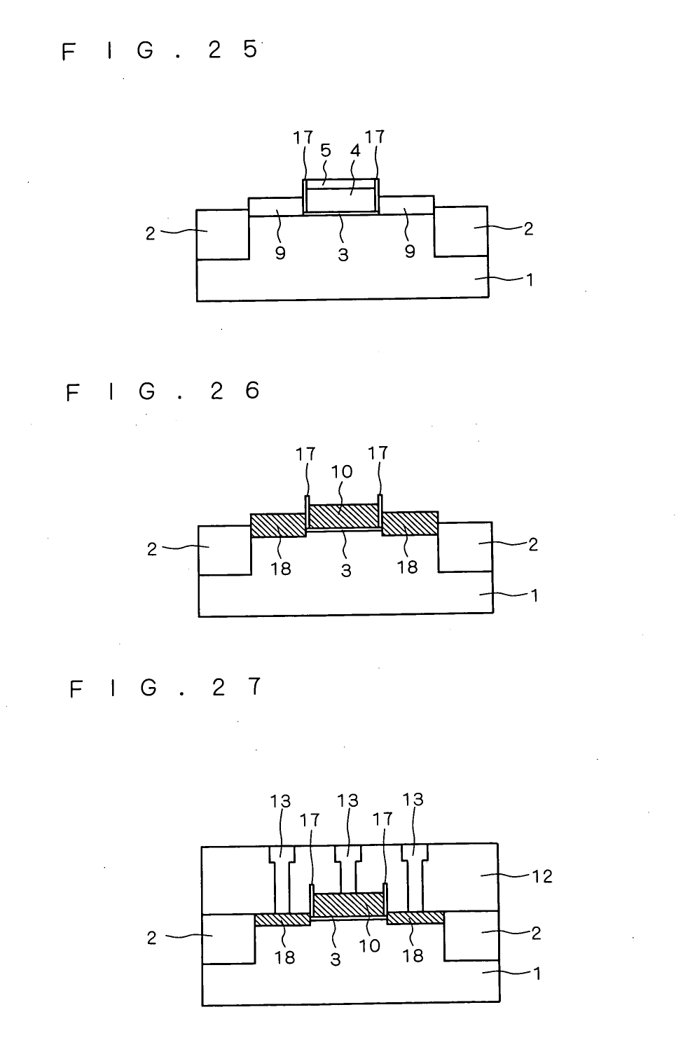

FIG. 23 is a sectional view showing a configuration of a semiconductor device according to a fifth embodiment of the present invention.

An element isolation oxide film 2 is formed on a semiconductor substrate 1 so as to encircle a circumference of an element formation region. A full-silicide gate electrode 10 is formed via a gate insulating film 3 on the semiconductor substrate 1 in the element formation region. A Schottky source/drain (source/drain region) 18 that effects Schottky junction with the semiconductor substrate 1 and is formed of a metal silicide film is formed so as to sandwich the full-silicide gate electrode 10.

Herein, the Schottky source/drain 18 extends up to the surface of the semiconductor substrate 1, and its thickness is substantially equal to the thickness of the full-silicide gate electrode 10.

Next, a manufacturing method of the semiconductor device according to this embodiment will be explained with reference to FIGS. 24 to 26.

Firstly, the element isolation oxide film 2 is formed on the semiconductor substrate 1, and then, a silicon nitride oxide film having a thickness of about 1.5 nm, a polysilicon film 4 having a thickness of about 100 nm and a silicon oxide film 5 having a thickness of about 20 nm are sequentially formed, in accordance with the process same as that in the first embodiment. Subsequently, the silicon oxide film 5 and the polysilicon film 4 are sequentially patterned with a photoengraving pattern as a mask, thereby forming a polysilicon gate electrode 4.

Then, a silicon nitride film having a thickness of 3 nm is deposited on the entire face. This silicon nitride film is etched back to form the sidewall insulating films 7 on the sidewalls of the polysilicon gate electrode 4 and gate insulating film 3 (FIG. 24).

Subsequently, a silicon film 9 is deposited with a thickness of about 80 nm only on the source/drain formation region by a selective CVD method (FIG. 25).

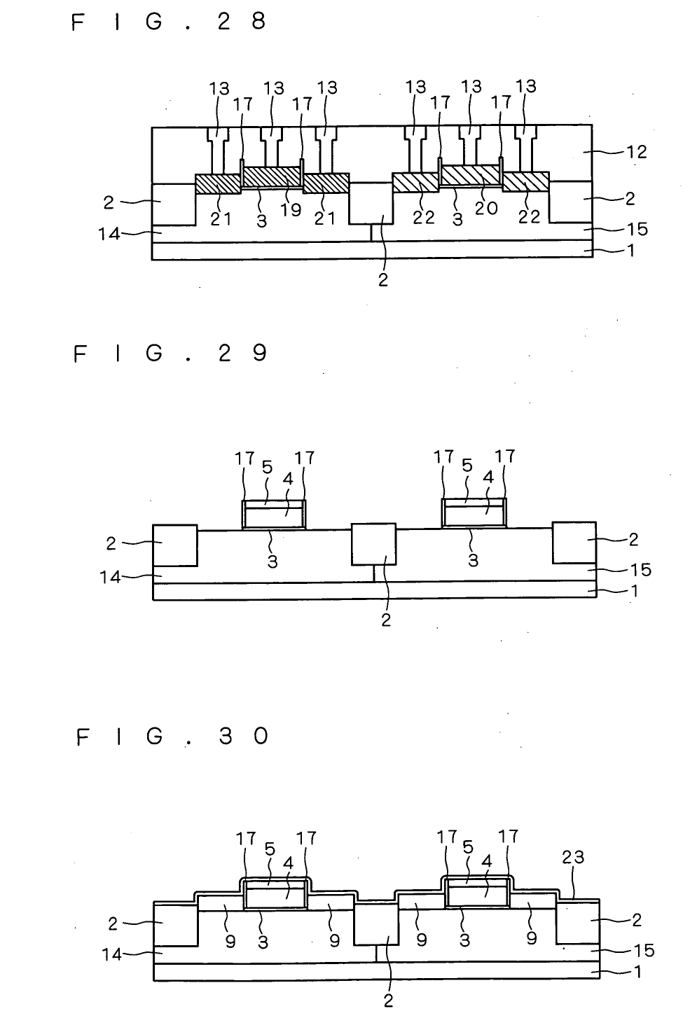

Subsequently, the silicon oxide film 5 on the polysilicon gate electrode 4 is removed to expose the surface of the polysilicon gate electrode 4. Then, a nickel film having a thickness of about 70 nm is deposited. Heat treatment with about 400° C. is applied thereon, thereby metal-siliciding the whole polysilicon gate electrode 4 and, simultaneously, siliciding the silicon film 9 formed on the source/drain region and a part of the semiconductor substrate 1. Schottky junction is effected with the semiconductor substrate 1 by siliciding a part of the semiconductor substrate 1. Thereafter, unreacted nickel film is removed, thereby forming the full-silicide gate electrode 10 and the Schottky source/drain 18 extending up to the semiconductor substrate 1 (FIG. 26).

Herein, the thickness of the full-silicide gate electrode 10 and the thickness of the Schottky source/drain 18 are substantially equal to each other. Then, the interlayer film 12 is formed, contact is opened, and wiring layers 13 are formed, thereby completing the semiconductor element (MISFET) shown in FIG. 23.

In the semiconductor device according to this embodiment, the source/drain region is formed by the Schottky source/drain 18. Since the Schottky source/drain 18 effects the Schottky junction with the semiconductor substrate 1, the Schottky source/drain can be formed to be thick without a problem of increase in leak current.

In the semiconductor device according to this embodiment, since the thickness of the metal silicide film 11 forming the Schottky source/drain 18 can be increased, resistance can be reduced, thereby being capable of realizing high-speed operation.

The silicide forming process is performed once in this embodiment, so that the manufacturing process is simplified compared to the conventional method, thereby being capable of reducing manufacturing cost. Additionally, a step between the silicide film forming the Schottky source/drain 18 and the full-silicide gate electrode 10 can be made smaller than as conventionally. Accordingly, upon forming the wiring layers 13, the process margin for the contact hole is enlarged to thereby be capable of enhancing yield.

### Sixth Embodiment

FIG. 27 is a sectional view showing a configuration of a semiconductor device according to a sixth embodiment of the present invention.

An element isolation oxide film 2 is formed on a semiconductor substrate 1 so as to encircle a circumference of an element formation region. A full-silicide gate electrode 10 is formed via a gate insulating film 3 on the semiconductor substrate 1 in the element formation region. A Schottky source/drain 18 that effects Schottky junction with the semiconductor substrate 1 and is formed of a metal silicide film is formed so as to sandwich the full-silicide gate electrode 10.

Herein, the Schottky source/drain 18 extends up to the surface of the semiconductor substrate 1, and its thickness is smaller than the thickness of the full-silicide gate electrode 10.

Further, the Schottky source/drain 18 contains an element (e.g., nitrogen) for suppressing the silicide reaction.

A manufacturing method of the semiconductor device according to this embodiment is the same as that explained in the fifth embodiment, except for forming the thin Schottky source/drain 18.

In order to form the thin Schottky source/drain 18, the silicon film 9 is formed to be thin and an element such as nitrogen ion for suppressing the silicidation is implanted, or nitrogen is implanted in-situ with the formation of the silicon film 9. The method is the same as that explained in the second or third embodiment, so that the detailed explanation is omitted.

In the semiconductor device according to this embodiment, since the thickness of the metal silicide film forming the Schottky source/drain 18 can be increased, resistance can be reduced, thereby being capable of realizing high-speed operation.

Since the metal silicide film forming the Schottky source/drain 18 is thinner than the silicide film of the full-silicide gate electrode 10, the sufficient distance between the metal silicide film forming the Schottky source/drain 18 and the full-silicide gate electrode 10 can be secured. Therefore, short-circuit between both electrodes can effectively be avoided, thereby enhancing yield.

The silicide forming process is performed once in this embodiment, so that the manufacturing process is simplified compared to the conventional method, thereby being capable of reducing manufacturing cost. Additionally, a step between the silicide film forming the Schottky source/drain 18 and the silicide film of the full-silicide gate electrode 10 can be made smaller than as conventionally. Accordingly, upon forming the wiring layers 13, the process margin for the contact hole is enlarged to thereby be capable of enhancing yield.

### Seventh Embodiment

FIG. 28 is a sectional view showing a configuration of a semiconductor device according to a seventh embodiment.

An element isolation oxide film 2 is formed on a semiconductor substrate 1. A p well 14 is formed on an N-type MISFET formation region and an n well 15 is formed on a P-type MISFET formation region. A full-silicide gate electrode 19 formed of erbium silicide is formed on the N-type MISFET formation region and a full-silicide gate electrode 20 formed of platinum silicide is formed on the P-type MISFET formation region, via the gate insulating film 3. A Schottky source/drain 21 formed of erbium silicide is formed on the N-type MISFET formation region and a Schottky source/drain 22 formed of platinum silicide is formed on the P-type MISFET, via a channel region below the full-silicide gate electrode 20.

Herein, the metal silicide film forming the Schottky sources/drains 21 and 22 extends up to the surface of the semiconductor substrate 1. Its thickness is substantially equal to those of the full-silicide gate electrodes 19 and 20. Further, the Schottky source/drain effects the Schottky junction with the semiconductor substrate 1.

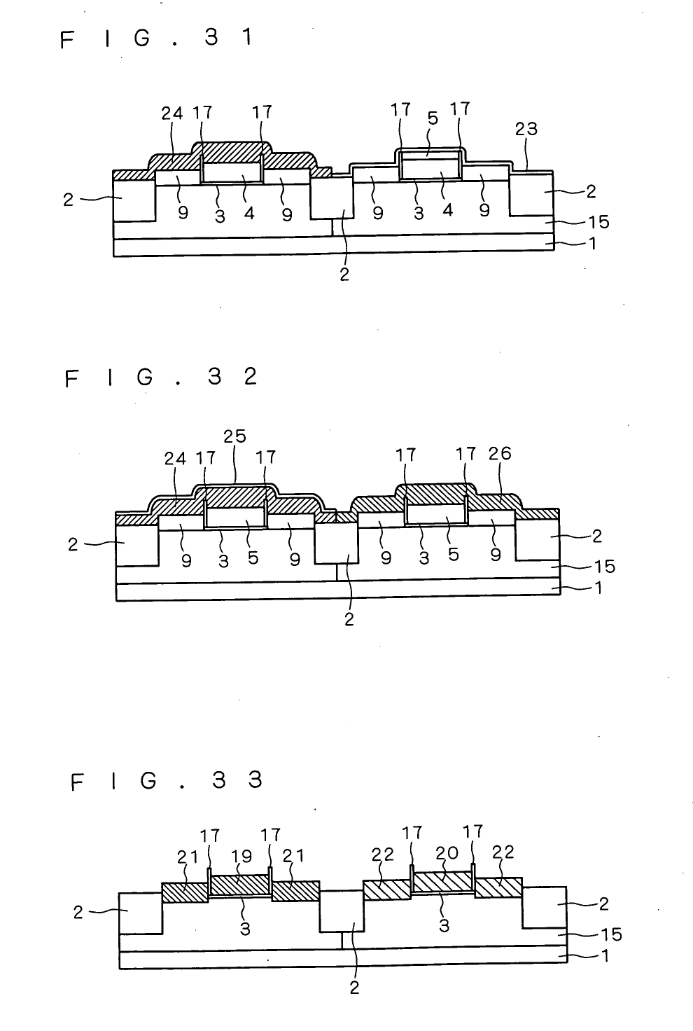

Subsequently, a manufacturing method of the semiconductor device according to this embodiment will be explained with reference to FIGS. 29 to 33.

In accordance with the same process as that of the third embodiment, the element isolation oxide film 2, the n well 14, the p well 15, the polysilicon gate electrode 4 and the like are formed (see FIGS. 12 and 13).

Subsequently, a silicon nitride film having a thickness of about 3 nm is deposited on the entire surface and etched back, thereby forming the gate insulating film 3 and sidewall insulating films 17 at the sidewall of the polysilicon gate electrode 4 (FIG. 29).

Then, a silicon film 9 is deposited with a thickness of about 80 nm only on the semiconductor substrate 1 and in the source/drain formation region by the selective CVD method, thereby forming a silicon oxide film 23 having a thickness of about 20 nm on the entire surface (FIG. 30).

Next, the silicon oxide film 23 on the N-type MISFET formation region and the silicon oxide film 5 on the polysilicon gate electrode 4 are removed with a photoengraving pattern as a mask, thereby exposing the surface of the silicon film 9 and the surface of the polysilicon gate electrode 4. Then, an erbium film (first metal film) 24 having a thickness of about 70 nm is deposited thereon (FIG. 31).

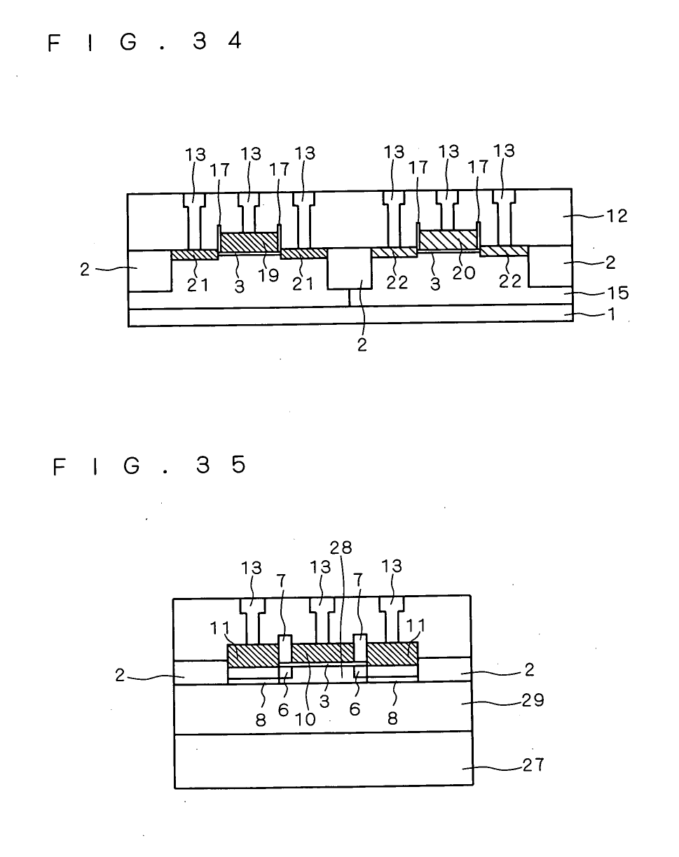

Subsequently, a silicon oxide film 25 is formed, and the silicon oxide film 25 on the P-type MISFET formation region and the silicon oxide film 5 on the polysilicon gate electrode 4 are removed with a photoengraving pattern as a mask, thereby exposing the surface of the silicon film 9 and the surface of the polysilicon gate electrode 4. Then, a platinum film (second metal film) 26 having a thickness of about 70 nm is deposited thereon (FIG. 32). Then, after the silicon oxide film 25 on the N-type MISFET formation region is removed, heat treatment of about 400° C. is applied thereon, thereby erbium-siliciding the whole polysilicon gate electrode 4 on the N-type MISFET formation region. Thus, the full-silicide gate electrode 19 is formed. At the same time, the silicon film 9 on the source/drain region on the N-type MISFET and a part of the semiconductor substrate 1 are silicided, thereby forming Schottky source/drain 21 formed of erbium silicide.

In the P-type MISFET formation region, the whole polysilicon gate electrode 4 on the P-type MISFET formation region is platinum-silicided simultaneous with the N-type MISFET formation region, thereby forming the full-silicide gate electrode 20. At the same time, the silicon film 9 on the source/drain region on the P-type MISFET and a part of the semiconductor substrate 1 are silicided, thereby forming Schottky source/drain 22 formed of platinum silicide (FIG. 33).

Herein, the thicknesses of the full-silicide gate electrodes 19 and 20, the thickness of the Schottky source/drain 21 formed of erbium silicide and the thickness of the Schottky source/drain 22 formed of platinum silicide are substantially equal to one another.

Then, the interlayer film 12 is formed, contact is opened, and wiring layers 13 are formed, thereby completing the semiconductor element (CMISFET) shown in FIG. 28.

In the semiconductor device according to this embodiment, the thickness of the metal silicide film forming the Schottky sources/drains 21 and 22 can be increased, so that resistance can be reduced, thereby being capable of realizing high-speed operation.

The Schottky sources/drains 21 and 22 having optimum metal silicide films, which are different from each other, can be formed, respectively, on the N-type MISFET and P-type MISFET, thereby being capable of realizing a source/drain structure having optimum Schottky barrier. As a result, the driving ability of the MISFET can be enhanced, thereby being capable of realizing high-speed operation.

The silicide forming process is performed once in this embodiment, so that the manufacturing process is simplified compared to the conventional method, thereby being capable of reducing manufacturing cost. Additionally, a step between the Schottky sources/drains 21 and 22 and the full-silicide gate electrodes 19 and 20 can be made smaller than as conventionally. Accordingly, upon forming the wiring layers 13, the process margin for the contact hole is enlarged to thereby be capable of enhancing yield.

### Eighth Embodiment

FIG. 34 is a sectional view showing a configuration of a semiconductor device according to an eighth embodiment. An element isolation oxide film 2 is formed on a semiconductor substrate 1. A p well 14 is formed on an N-type MISFET formation region and an n well 15 is formed on a P-type MISFET formation region. A full-silicide gate electrode 19 formed of erbium silicide is formed on the N-type MISFET formation region and a full-silicide gate electrode 20 formed of platinum silicide is formed on the P-type MISFET, via the gate insulating film 3. A Schottky source/drain 21 formed of erbium silicide is formed on the N-type MISFET formation region and a Schottky source/drain 22 formed of platinum silicide is formed on the P-type MISFET, via a channel region.

Herein, the metal silicide film forming the Schottky sources/drains 21 and 22 extends up to the surface of the semiconductor substrate 1. Its thickness is smaller than those of the full-silicide gate electrodes 19 and 20.

It is apparent that the semiconductor device of this embodiment can be formed in accordance with the manufacturing method explained in the seventh embodiment, wherein the silicon film 9 is made thin and an element for suppressing the silicidation such as nitrogen ion is implanted into the silicon film 9 formed on the source/drain region or nitrogen is implanted in-situ into the silicon film. Therefore, the detailed explanation is omitted.

In the semiconductor device according to this embodiment, the source/drain region is formed by the Schottky sources/drains 21 and 22. Since the Schottky sources/drains 21 and 22 effect the Schottky junction with the semiconductor substrate 1, the Schottky sources/drains can be formed to be thick without a problem of increase in leak current.

In this embodiment, since the thickness of the metal silicide film forming the Schottky sources/drains 20 and 21 can be increased, resistance can be reduced, thereby being capable of realizing high-speed operation.

Since the metal silicide film forming the Schottky sources/drains 21 and 22 is thinner than the full-silicide gate electrodes 19 and 20, the sufficient distance between the metal silicide film forming the Schottky sources/drains 21 and 22 and the silicide film of the full-silicide gate electrodes 19 and 20 can be secured. Therefore, short-circuit between both electrodes can effectively be avoided, thereby enhancing yield.

The metal silicide Schottky sources/drains having optimum materials, which are different from each other, can be formed, respectively, on the N-type MISFET and the P-type MISFET, thereby being capable of realizing a source/drain structure having optimum Schottky barrier. As a result, the driving ability of the MISFET can be enhanced, thereby being capable of realizing high-speed operation.

The silicide forming process is performed once in this embodiment, so that the manufacturing process is simplified compared to the conventional method, thereby being capable of reducing manufacturing cost.

Additionally, a step between the silicide film forming the Schottky sources/drains 21 and 22 and the silicide film of the full-silicide gate electrode 10 can be made smaller than as conventionally. Accordingly, upon forming the wiring layers 13, the process margin for the contact hole is enlarged to thereby be capable of enhancing yield.

### Ninth Embodiment

FIG. 35 is a sectional view showing a configuration of a semiconductor device according to a ninth embodiment.

The semiconductor device according to this embodiment uses an SOI (Silicon On Insulator) substrate instead of the silicon substrate 1 in the semiconductor device shown in the first embodiment. The other configurations are the same as those of the first embodiment, so that the detailed explanation is omitted.

The semiconductor device according to this embodiment can be realized by the manufacturing method explained in the first embodiment except that the semiconductor substrate 1 is changed to the SOI substrate, so that the detailed explanation of the manufacturing method is also omitted.

Herein, the SOI substrate is made of a BOX oxide film 29 formed on a silicon substrate 27 and an SOI film 28 formed on the BOX oxide film 29.

In the case of using the SOI substrate, the depth of the source/drain diffusion layer 8 is determined in accordance with the thickness of the SOI film 28. Therefore, in case where the metal silicide film is formed in the SOI film, it is difficult to secure the distance from an interface between the metal silicide film and the SOI film 28 to an interface between the source/drain diffusion layer 8 and the BOX oxide film 29.

However, the metal silicide film 11 is formed on the source/drain diffusion layer 8 in the semiconductor device according to this embodiment, whereby the aforementioned distance can be easily secured.

As a result, in the case of using the SOI substrate, the effect obtained by the first embodiment can be obtained more effectively.

Although the first to sixth embodiments illustrate that nickel is used as a silicide material, the same effect can be obtained by using a silicide material such as cobalt, titanium, palladium, platinum, erbium, or the like.

Although the first to ninth embodiments illustrate that a silicon nitride oxide film is used as the gate insulating film 3, the same effect can be obtained by using an insulating film having high dielectric constant such as hafnium oxide, lanthanum oxide, or the like.

Although the ninth embodiment illustrates that the SOI substrate is applied to the first embodiment, the same effect can be obtained by applying the SOI substrate to the semiconductor devices according to the second to eighth embodiments.

Although the seventh and eighth embodiments show that erbium silicide and platinum silicide are used, it is apparent that the effect of the present invention can be obtained by using other silicide combination.

Although the first, second, fifth, sixth and ninth embodiments illustrate the manufacture of the N-type MISFET for brief explanation, it is apparent that a P-type MISFET can be manufactured by reversing the conductive type of a dopant and CMISFET can be manufactured by combining both of them.

Although the seventh embodiment illustrates that the erbium silicide and platinum silicide are formed by the same heat treatment, it is apparent that the same effect can be obtained by siliciding each metal film under different heat treatment condition after depositing each metal film.

Although the first to ninth embodiments do not describe the implantation of dopant into the gate electrode, the dopant may be implanted upon forming the source/drain diffusion layer, or a dopant may be implanted beforehand after forming the polysilicon gate electrode 4 to control a work function.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a full-silicide gate electrode which is formed on a semiconductor substrate via a gate insulating film, and is fully silicided; and
a source/drain region which has an upper main face formed higher than said semiconductor substrate so as to sandwich said full-silicide gate electrode, wherein
said source/drain region includes a metal silicide film at least on the side of said upper main face.

2. The semiconductor device according to claim 1, wherein
said source/drain region further includes a source/drain diffusion layer formed on the surface of said semiconductor substrate so as to sandwich a channel region below said full-silicide gate electrode.

3. The semiconductor device according to claim 1, wherein
said source/drain region further includes a silicon germanium layer formed on the surface of said semiconductor substrate so as to sandwich a channel region below said full-silicide gate electrode.

4. The semiconductor device according to claim 1, wherein
said source/drain region is a Schottky source/drain formed of a metal silicide film effecting a Schottky junction with said semiconductor substrate.

5. The semiconductor device according to claim 1, wherein
the thickness of said metal silicide film is substantially equal to the thickness of said full-silicide gate electrode.

6. The semiconductor device according to claim 1, wherein
the thickness of said metal silicide film is smaller than the thickness of said full-silicide gate electrode.

7. The semiconductor device according to claim 6, wherein
said metal silicide film contains an element for suppressing silicidation.

8. The semiconductor device according to claim 1, wherein
the material of said metal silicide film is different between an N-type MISFET and a P-type MISFET.

9. The semiconductor device according to claim 1, wherein
said semiconductor substrate is an SOI substrate.

10. A manufacturing method of a semiconductor device comprising a full-silicide gate electrode which is formed on a semiconductor substrate via a gate insulating film and is fully silicided, and a source/drain region which has an upper main face formed higher than said semiconductor substrate so as to sandwich said full-silicide gate electrode, said source/drain region including a metal silicide film at least on the side of said upper main face,
the method comprising the steps of:
(a) forming a polysilicon gate electrode formed of a polysilicon film on said semiconductor substrate via said gate insulating film;
(b) forming a silicon film on said semiconductor substrate in said source/drain region;
(c) forming a metal film so as to cover said polysilicon gate electrode and said silicon film; and
(d) forming said full-silicide gate electrode and said metal silicide film by simultaneously siliciding said whole polysilicon gate electrode and a part of or whole of said silicon film.

11. The manufacturing method according to claim 10, further comprising the step of:
forming a source/drain diffusion layer on the surface of said semiconductor substrate in said source/drain region.

12. The manufacturing method according to claim 10, further comprising the step of:
forming a recess region on said semiconductor substrate in said source/drain region, wherein
said step (b) forms a silicon film containing germanium in said recess region.

13. The manufacturing method according to claim 10, wherein
said step (d) includes the step of siliciding said whole silicon film and, also, siliciding a part of said semiconductor substrate below said silicon film, thereby forming a Schottky source/drain.

14. The manufacturing method according to claim 10, wherein
said step (b) includes the step of forming said silicon film having a thickness substantially equal to the thickness of said polysilicon gate electrode.

15. The manufacturing method according to claim 10, wherein
said step (b) includes the step of forming said silicon film having a thickness smaller than the thickness of said polysilicon gate electrode.

16. The manufacturing method according to claim 15, further comprising the step of:
implanting an element for suppressing silicidation into said silicon film.

17. The manufacturing method according to claim 15, wherein
said step (b) includes the step of forming said silicon film while implanting an element for suppressing silicidation.

18. The manufacturing method according to claim 10, wherein
said step (c) includes the step of forming a first metal film on said N-type MISFET formation region, and the step of forming a second metal film on said P-type MISFET formation region.

19. The manufacturing method according to claim 10, wherein
said semiconductor substrate is an SOI substrate.
